(19) United States
(12) Patent Application Publication
(10) Pub. No.: US 2026/0073973 A1
(43) Pub. Date: Mar. 12, 2026

(54) METHOD AND APPARATUS TO SUPPORT REDUCED DENSITY ROUTING OF DYNAMIC RANDOM ACCESS MEMORY ON SMALL FORM FACTOR PRINTED CIRCUIT BOARDS

(71) Applicant: Micron Technology, Inc., Boise, ID (US)

(72) Inventor: Michael R. SPICA, Eagle, ID (US)

(21) Appl. No.: 19/279,413

(22) Filed: Jul. 24, 2025

Related U.S. Application Data
(60) Provisional application No. 63/693,962, filed on Sep. 12, 2024.

(51) Int. Cl. G11C 11/4093; H01L 25/00; H01L 25/065; H01L 25/18; H10B 80/00

(52) U.S. Cl. CPC G11C 11/4093; H10B 80/00; H10W 90/00; H10W 90/722; H10W 90/724

(57) ABSTRACT

A semiconductor device assembly includes a circuit substrate including one or more high-speed serial channels; a controller arranged on the circuit substrate, the controller includes a first serial communication interface coupled to the one or more high-speed serial channels; a memory integrated circuit (IC) including a first parallel communication interface configured to transmit first parallel signals; and a serial-parallel management IC arranged on the circuit substrate, the serial-parallel management IC including a second serial communication interface coupled to the one or more high-speed serial channels for communication with the controller, and a second parallel communication interface coupled to the first parallel communication interface of the memory chip. The serial-parallel management IC is configured to receive the first parallel signals, convert the first parallel signals into one or more first serial signals, and transmit the one or more first serial signals to the controller via the second serial communication interface.

### CROSS-REFERENCE TO RELATED APPLICATION

This Patent Application claims priority to U.S. Provisional Patent Application No. 63/693,962, filed on Sep. 12, 2024, entitled “METHOD AND APPARATUS TO SUPPORT REDUCED DENSITY ROUTING OF DYNAMIC RANDOM ACCESS MEMORY ON SMALL FORM FACTOR PRINTED CIRCUIT BOARDS,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to reduced density routing of dynamic random access memory on small form factor printed circuit boards.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram illustrating an example configured to support reduced density routing of dynamic random access memory signals on circuit substrates.

FIG. 2A shows a semiconductor device assembly according to one or more implementations.

FIG. 2B shows a semiconductor device assembly according to one or more implementations.

FIG. 3 is a flowchart of an example method of manufacturing a semiconductor device assembly.

FIG. 4 is a flowchart of an example method of communicating between a controller and a memory IC.

### DETAILED DESCRIPTION

In the realm of computing, particularly in the context of high-speed memory access and data transfer, compute express link (CXL) technology represents a significant advancement. CXL is designed to facilitate efficient communication between high-speed processors and memory devices. A primary factor influencing CXL performance is the number of available communication channels to a memory device. High memory access speeds drive the necessity for longer physical traces on printed circuit boards (PCBs) of CXL devices, leading to increased wire congestion. This wire congestion restricts layout flexibility and an amount of dynamic random-access memory (DRAM) that can be placed on a PCB. Moreover, additional layers may need to be added to the PCB to increase channel density, which increases the cost of the PCB.

Typical DRAM operations use a wide interface where all signals, including data signals (e.g., DQ[7:0])], are handled in parallel and arrive on the same clock edge. Parallel communication interfaces may add to the wire congestion on the PCB, since parallel communications require a large number of wires. Again, additional layers may need to be added to the PCB to accommodate for the large number of wires as additional DRAMs are mounted to the PCB, which may increase production costs and may introduce routing and layout complexities.

Some implementations described herein provide a semiconductor device assembly that supports reduced density routing of DRAM on small form factor PCBs. For example, a semiconductor device assembly may comprise a serial-parallel management system-on-chip (SOC) arranged on a circuit substrate, such as a PCB, that includes one or more high-speed serial channels. The serial-parallel management SOC may have a parallel communication interface coupled to a memory IC (e.g., DRAM) and a serial communication interface coupled to a controller (e.g., a memory controller, such as a CXL controller) via the one or more high-speed serial channels. The serial-parallel management SOC may receive parallel signals from the memory IC, convert the parallel signals into serial signals, and transmit the serial signals to the controller. Conversely, the serial-parallel management SOC may receive serial signals from the controller, convert the serial signals into parallel signals, and transmit the parallel signals to the memory IC. The serial-parallel management SOC may be configured to manage and convert parallel and serial communications. A serial-parallel conversion may enable serial channels to be used on the PCB instead of parallel channels, thereby reducing a number of wires or traces needed for routing on the PCB. In some implementations, the one or more high-speed serial channels of the circuit substrate may include differential signaling channels which transmit signals via differential signaling. Additionally, the memory IC may be vertically integrated with the serial-parallel management SOC in either a 3D chip stack configuration or a 3D wafer stack configuration, which may aid in optimizing space and reducing wire congestion.

In this way, some implementations may reduce wire congestion on PCBs, reducing the number and the length of the physical traces required for high-speed memory operation. By leveraging high-speed serial communication, some implementations may improve channel density without necessitating additional PCB layers, which may reduce production costs and abate physical limitations. Some implementations may advance the state of semiconductor device assembly by increasing the efficiency of resource utilization. A conversion from a bandwidth-consumptive parallel data transfer mechanism to a streamlined high-speed serial protocol may enable higher density DRAM devices to be manufactured without increasing a size and/or cost of the circuit substrate. Some implementations may support CXL architectures and can be instrumental in accelerating the speed of data transfers and increasing memory densities of memory devices.

For example, to mitigate wire congestion in a circuit substrate, high speed serial signaling with an N: 1 conversion operation can be performed by the serial-parallel management SOC to reduce the wire congestion and maintain a bandwidth without a latency degradation. For converting an eight-wire parallel data interface (e.g., DQ[7:0]) down to a single serial channel without latency reduction, a serial communication interface should run serially at at least eight times a transmission rate of a parallel communication interface in order to compress all parallel channels into a single serial signal. For example, the eight-wire parallel data interface with each parallel channel running at 1 giga transfers per second (GTS), 8 GTS in total for the parallel communication interface, may be translated into an 8 GTS serial operation such that there is no negative impact on latency. Put another way, a serial channel would need to run at least at an equivalent rate with minimal channel link overhead. Thus, to convert parallel data into serial data, losslessly, would require that a minimum of an 8×faster serial channel can meet the same data rate as the parallel communication interface. However, the serial transfer rate may need to be faster than the parallel transfer rate by at least 10% to accommodate for link management overhead. Thus, 1 GTS per parallel data line may be converted into an 8 GTS serial channel +10% or into a 9 GTS serial channel.

A differential signaling channel used for high-speed serial communications may be used to reduce eight physical parallel traces to one serial channel with two physical signal traces, with a factor of four reduction in a number of physical traces and an improved drive along the signal path. Thus, the serial-parallel conversion may allow much higher DRAM densities and significantly more channels to be routed on the circuit substrate, with lower signal integrity (SI) cost.

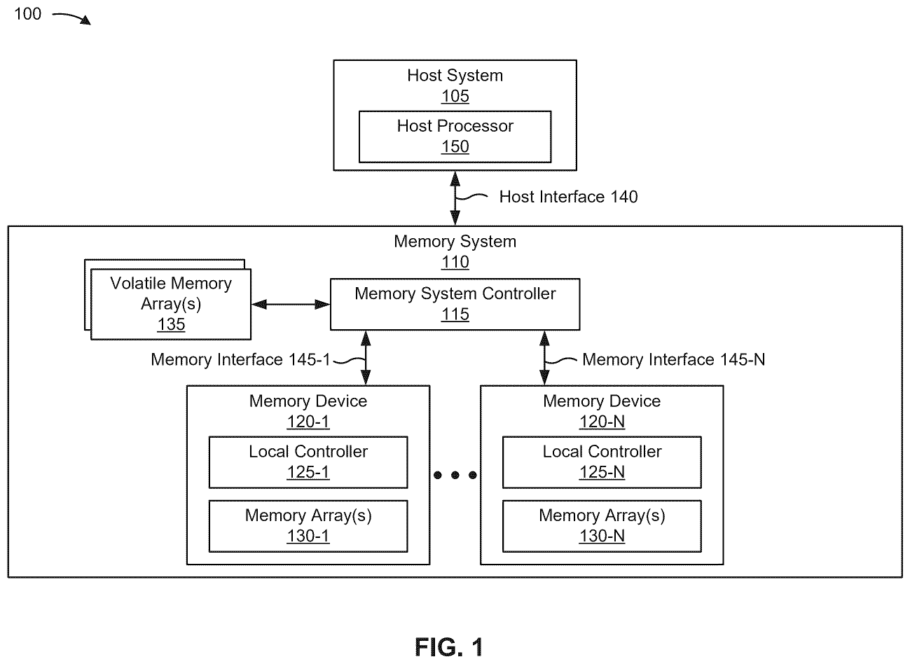

FIG. 1 is a diagram illustrating an example system 100 configured to support reduced density routing of DRAM signals on circuit substrates. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), a CXL memory module, and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, a CXL controller connected to DRAM, a CPU, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, a DIMM interface, and/or a CXL interface (e.g., a PCIe/CXL interface).

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some examples, the system 100 may be associated with a CXL standard and/or protocol (e.g., the system 100 may utilize a CXL protocol to communicate between the host system 105, sometimes referred to as a CXL compliant host or simply a CXL host, and the memory system 110, sometimes referred to as a CXL compliant memory system or simply a CXL memory system). In that regard, the host system 105 may be a CXL host and the memory system 110 may be a CXL compliant memory system. The CXL host and the CXL compliant memory system may communicate via the host interface 140, which may include a CXL bus (e.g., a PCIe/CXL interface, an Ultra Accelerator link (UALink) interface, an Ethernet interface, an ultra-Ethernet interface, and/or a similar interface), among other examples.

In some examples, the memory system 110 may be a system that complies with the CXL standard and/or protocol, such as for a purpose of communicating with one or more host devices (e.g., the host system 105). CXL is an open standard that may enable high-speed CPU-to-device and CPU-to-memory interconnects designed to accelerate next-generation performance. The CXL standard may enable memory coherency between the CPU memory space and memory on attached devices, which allows resource sharing for higher performance, reduced software stack complexity, and lower overall system cost. CXL is designed to be an industry open standard for enabling an interface for high-speed communications. CXL technology utilizes the PCIe infrastructure, leveraging PCIe physical and electrical interfaces to provide an advanced protocol in areas such as input/output (I/O) protocol, memory protocol, and coherency interface.

In some implementations, one or more systems, devices, apparatuses, components, and/or controllers of FIG. 1 may be configured to include a circuit substrate comprising one or more high-speed serial channels; a controller arranged on the circuit substrate, wherein the controller comprises a first serial communication interface coupled to the one or more high-speed serial channels; a memory chip comprising a first parallel communication interface configured to transmit first parallel signals; and a serial management SOC arranged on the circuit substrate, wherein the serial management SOC comprises a second serial communication interface coupled to the one or more high-speed serial channels for communication with the controller, and a second parallel communication interface coupled to the first parallel communication interface of the memory chip, wherein the serial management SOC is configured to receive the first parallel signals from the memory chip via the second parallel communication interface, convert the first parallel signals into one or more first serial signals, and transmit the one or more first serial signals to the controller via the second serial communication interface and the one or more high-speed serial channels.

In some implementations, one or more systems, devices, apparatuses, components, and/or controllers of FIG. 1 may be configured to include a circuit substrate comprising one or more high-speed serial channels; a controller arranged on the circuit substrate, wherein the controller comprises a first serial communication interface coupled to the one or more high-speed serial channels; a memory IC comprising a first parallel communication interface configured to transmit first parallel signals; and a serial-parallel management IC arranged on the circuit substrate, wherein the serial-parallel management IC comprises a second serial communication interface coupled to the one or more high-speed serial channels for communication with the controller, and a second parallel communication interface coupled to the first parallel communication interface of the memory IC, wherein the serial-parallel management IC is configured to receive the first parallel signals from the memory IC via the second parallel communication interface, convert the first parallel signals into one or more first serial signals, and transmit the one or more first serial signals to the controller via the second serial communication interface and the one or more high-speed serial channels.

In some implementations, one or more systems, devices, apparatuses, components, and/or controllers of FIG. 1 may be configured to include a circuit substrate comprising one or more serial channels; a CXL controller arranged on the circuit substrate, wherein the CXL controller comprises a first serial communication interface coupled to the one or more serial channels; a DRAM IC comprising a first parallel communication interface configured to transmit first parallel signals; and a serial-parallel converter IC arranged on the circuit substrate, wherein the serial-parallel converter IC comprises a second serial communication interface coupled to the one or more serial channels for communication with the CXL controller, and a second parallel communication interface coupled to the first parallel communication interface of the DRAM IC, wherein the serial-parallel converter IC is configured to receive the first parallel signals from the DRAM IC via the second parallel communication interface, convert the first parallel signals into one or more first serial signals, and transmit the one or more first serial signals to the CXL controller via the second serial communication interface and the one or more serial channels.

In some implementations, one or more systems, devices, apparatuses, components, and/or controllers of FIG. 1 may be configured to mount a controller on a circuit substrate comprising one or more high-speed serial channels, including coupling a first serial communication interface of the controller to the one or more high-speed serial channels; mount a serial-parallel management IC on the circuit substrate, including coupling a second serial communication interface of the serial-parallel management IC to the one or more high-speed serial channels for serial communication between the serial-parallel management IC and the controller; and mount a memory IC on the serial-parallel management IC, including coupling a first parallel communication interface of the memory IC to a second parallel communication interface of the serial-parallel management IC for parallel communication between the memory IC and the serial-parallel management IC, wherein the serial-parallel management IC is configured as a serial-parallel communication interface between the controller and the memory IC.

In some implementations, one or more systems, devices, apparatuses, components, and/or controllers of FIG. 1 may be configured to transmit first parallel signals; receive the first parallel signals from the first parallel communication interface; convert the first parallel signals into one or more first serial signals; transmit the one or more first serial signals; and receive the one or more first serial signals from the first serial communication interface, wherein the first serial communication interface and the second serial communication interface are coupled by one or more serial channels.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

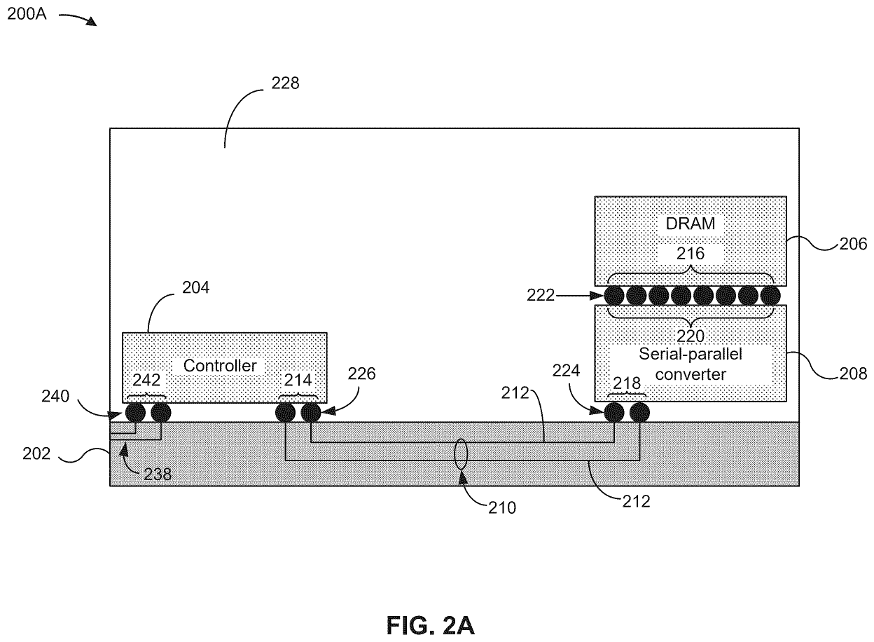

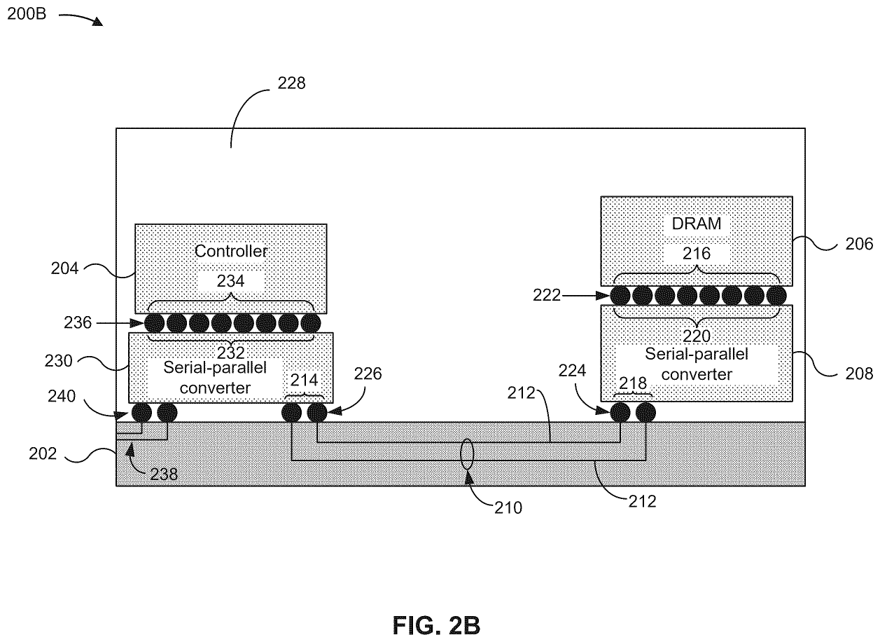

FIG. 2A shows a semiconductor device assembly 200A according to one or more implementations. The semiconductor device assembly 200A may include a circuit substrate 202, a controller 204, a memory IC 206, and a serial-parallel management IC 208.

The circuit substrate 202 may be a PCB on which the controller 204, the memory IC 206, and the serial-parallel management IC 208 are mounted. The circuit substrate 202 may include one or more high-speed serial channels 210. In some implementations, each high-speed serial channel 210 may be a differential signaling channel comprising a pair of electrically conductive paths 212 (e.g., a pair of traces or wires). In the example of FIG. 2A, a single differential signaling channel is shown, where the single differential signaling channel is made up of two electrically conductive paths 212. In some implementations, the one or more high-speed serial channels 210 may include one or more serial data channels for transferring data (e.g., write data or read data). In some implementations, the one or more high-speed serial channels 210 may include one or more serial control channels for transferring control information, such as clock signals, strobe signals, command signals (e.g., read commands and/or read commands), address channels, and/or error correction channels). Thus, while only one high-speed serial channel 210 is shown in FIG. 2A, additional high-speed serial channels may be provided.

The controller 204 may be a memory controller, such as memory system controller 115 described in connection with FIG. 1. In some implementations, the controller 204 may be a CXL controller and/or may include a CXL processor. The controller 204 may include a first serial communication interface 214 coupled to the one or more high-speed serial channels 210.

The memory IC 206 may be a memory device, such as memory device 120 described in connection with FIG. 1. In some implementations, the memory IC 206 may be a DRAM IC that includes a volatile memory array (e.g., a DRAM array) that is managed by the controller 204. For example, the controller 204 may write data to and read data from the volatile memory array. In some implementations, the memory IC 206 is a memory chip (e.g., a memory die) in which components of the memory device are integrated. For example, a local controller, such as local controller 125 and a volatile memory array 135, as described in connection with FIG. 1, may be integrated in the memory chip. Thus, the memory IC 206 may be formed at a chip integration level. In some implementations, the memory IC 206 may be formed at a wafer integration level. For example, the memory IC 206 may be integrated in a wafer (e.g., a first wafer). Accordingly, the memory IC 206 shown in FIG. 2A may be representative of a memory chip or a wafer in which components of the memory IC 206 are integrated.

The memory IC 206 may include a first parallel communication interface 216 configured to transmit first parallel signals. For example, the first parallel communication interface 216 may be a data communication interface, such as a data queue (DQ) interface, configured to transmit and receive data signals in parallel on a clock edge. Thus, the first parallel communication interface 216 may include a first number of DQ terminals for transmitting the first parallel signals, with the first parallel signals being parallel data signals being read from the memory IC 206 (e.g., from DRAM). In some implementations, the number of DQ terminals may be eight (e.g., DQ[7:0]).

The serial-parallel management IC 208 may be a serial management SOC and/or a serial-parallel converter IC. The serial-parallel management IC 208 may be configured to convert parallel signals into serial signals and convert serial signals into parallel signals. Thus, the serial-parallel management IC 208 may include a serializer/deserializer, including a serial-to-parallel converter and a parallel-to-serial converter. In some implementations, the serial-parallel management IC 208 is a chip (e.g., an SOC) in which components of the serial-parallel management IC 208 are integrated. Thus, the serial-parallel management IC 208 may be formed at a chip integration level. In some implementations, the serial-parallel management IC 208 may be formed at a wafer integration level. For example, the serial-parallel management IC 208 may be integrated in a wafer (e.g., a second wafer). Accordingly, the serial-parallel management IC 208 shown in FIG. 2A may be representative of an SOC or a wafer in which components of the serial-parallel management IC 208 are integrated.

The serial-parallel management IC 208 may include a second serial communication interface 218 coupled to the one or more high-speed serial channels 210 for communication with the controller 204. Additionally, the serial-parallel management IC 208 may include a second parallel communication interface 220 coupled to the first parallel communication interface 216 of the memory IC 206. The serial-parallel management IC 208 may receive the first parallel signals from the memory IC via the second parallel communication interface 220, convert the first parallel signals into one or more first serial signals, and transmit the one or more first serial signals to the controller 204 via the second serial communication interface 218 and the one or more high-speed serial channels 210. In addition, the serial-parallel management IC 208 may receive one or more second serial signals at the second serial communication interface 218 from the controller 204, via the one or more high-speed serial channels 210, convert the one or more second serial signals into second parallel signals, and provide the second parallel signals to the memory IC 206 via the second parallel communication interface 220.

The semiconductor device assembly 200A may include conductive interface structures 222, conductive interface structures 224, and conductive interface structures 226. The conductive interface structures 222, 224, and 226 may include solder balls, bond pads, vias, or the like. The conductive interface structures 222 may electrically couple the first parallel communication interface 216 and the second parallel communication interface 220 for parallel signaling between the memory IC 206 and the serial-parallel management IC 208. The conductive interface structures 224 may electrically couple the second serial communication interface 218 and the one or more high-speed serial channels 210 for serial signaling between the serial-parallel management IC 208 and the controller 204. The conductive interface structures 226 may electrically couple the first serial communication interface 214 and the one or more high-speed serial channels 210 for serial signaling between the serial-parallel management IC 208 and the controller 204.

In some implementations, the memory IC 206 may be arranged on the serial-parallel management IC 208. Thus, the first parallel communication interface 216 and the second parallel communication interface 220 are vertically connected. In some implementations, the memory IC 206 may be arranged on the serial-parallel management IC 208 to form a three-dimensional (3D) IC, a chip stack, or a wafer stack. For example, when the memory IC 206 is a memory chip (e.g. a first chip) and the serial-parallel management IC 208 is an SOC (e.g., a second chip), the memory chip and the SOC may be vertically stacked to form a chip stack. When the memory IC 206 is integrated on a first wafer and the serial-parallel management IC 208 is integrated on a second wafer, the first wafer and the second wafer may be vertically stacked to form a wafer stack. The serial-parallel management IC 208 may be arranged between the memory IC 206 and the circuit substrate 202 in order to reduce a number of traces routed through the circuit substrate 202. As a result, the one or more high-speed serial channels 210 require fewer conductive paths than is required by the first parallel communication interface 216 and result in less signal path congestion within the circuit substrate 202.

In some implementations, the semiconductor device assembly 200A may include a package casing 228, such as a molding, disposed over the circuit substrate 202. The package casing 228 may encapsulate the controller 204, the memory IC 206, and the serial-parallel management IC 208 in order to protect the controller 204, the memory IC 206, and the serial-parallel management IC 208 from external elements.

The first parallel communication interface 216 and the second parallel communication interface 220 may each include a first number of DQ terminals for transmitting the first parallel signals and the second parallel signals as parallel data signals. The serial-parallel management IC 208 may be customized to a layout of the memory IC 206 such that the second parallel communication interface 220 matches a layout of the first parallel communication interface 216. The first serial communication interface 214 and the second serial communication interface 218 may each include a second number of DQ ports for transmitting the one or more first serial signals and the one or more second serial signals as serial data signals.

A terminal may include a single electrical connection. A port may include two terminals used in conjunction for differential signaling. In other words, a port may include two differential paths that form one serial channel. For example, each DQ port may correspond to a differential signaling channel that includes two respective terminals for a respective pair of electrically conductive paths 212. Thus, each high-speed serial channel may include two wires or two traces that form a differential signal pair configured to transmit signals via differential signaling. The first number of DQ terminals may be a first multiple of the second number of DQ ports, the first multiple being equal to the second number multiplied by a conversion factor. For example, the conversion factor may be eight, such that the first number of DQ terminals is eight and the second number of DQ ports is one. Thus, the first parallel communication interface 216 may include eight DQ terminals for eight parallel signals, and the second serial communication interface 218 may include a DQ port corresponding to a single differential signaling channel (e.g., two electrically conductive paths 212).

In addition, the first parallel communication interface 216 and the second parallel communication interface 220 may be configured to transfer parallel signals at a first transmission rate, the first serial communication interface and the second serial communication interface may be configured to transfer serial signals at a second transmission rate, and the second transmission rate may be equal to or greater than a second multiple of the first transmission rate. The second multiple may be equal to the first transmission rate multiplied by the conversion factor. For example, if the conversion factor is eight, the second transmission rate may be equal to or greater than eight times the first transmission rate. In some implementations, the second transmission rate may be at least eight times the first transmission rate plus 10% of the first transmission rate, to accommodate for link management overhead.

In some implementations, the conversion factor may be four, such that the first number of DQ terminals is eight and the second number of DQ ports is two (e.g., two differential signal pairs). Thus, eight parallel signal paths at the memory IC 206 may be reduced to four traces in the circuit substrate 202.

In some implementations, the conversion factor may be sixteen, such that the first number of DQ terminals is sixteen and the second number of DQ ports is one (e.g., one differential signal pair). Thus, sixteen parallel signal paths at the memory IC 206 may be reduced to two traces in the circuit substrate 202.

In some implementations, the first serial communication interface 214 may include sixteen ports with a transfer rate of 8 GTS per port, which can support 128 GTS (16×8) of available signal operation on a single unit. The number of serial ports and parallel terminals may be configurable, based on application and design.

In some implementations, the first serial communication interface 214 includes a first set of DQ terminals coupled to the one or more high-speed serial channels 210 and configured to receive the one or more first serial signals, and the second serial communication interface 218 may include a second set of DQ terminals coupled to the one or more high-speed serial channels 210 and configured to transmit the one or more first serial signals. In some implementations, the first parallel communication interface 216 includes at least eight parallel DQ terminals coupled to respective DQ terminals of the second parallel communication interface 220 for transferring the first parallel signals to the serial-parallel management IC 208. The first set of DQ terminals may be configured to transmit the one or more second serial signals. The second set of DQ terminals may be configured to receive the one or more second serial signals. The second parallel communication interface 220 may be configured to transfer the second parallel signals from the serial-parallel management IC 208 to the memory IC 206.

In some implementations, the controller 204 may include a serial-parallel converter for converting serial signals into parallel signals, and vice versa. A serial-to-parallel conversion may be used to obtain the same parallel bandwidth (e.g., the same DQ parallel bandwidth) that was originally present at the memory IC 206. A host communication interface 238 (e.g., a communication bus) may be provided for communicating with a host device (e.g., the host system 105). Conductive interface structures 240 may be provided to connect the controller 204 to the host communication interface 238. The host communication interface 238 may be a serial communication interface or a parallel communication interface. In some implementations, the host communication interface 238 may be a two-wire communication interface, such as PCIe. The controller 204 may have a corresponding host communication interface 242 coupled to the host communication interface 238 by the conductive interface structures 240.

Using serial connections between the controller 204 and the serial-parallel management IC 208 may reduce the cost of the controller 204 and the circuit substrate 202. For example, a number of interface terminals at the controller 204 and a number of conductive traces routed through the circuit substrate 202 can be reduced. A reduced number of conductive traces routed through the circuit substrate 202 may enable a number of PCB layers of the circuit substrate 202 to be reduced, thereby reducing the cost of the circuit substrate 202. Moreover, congestion of the conductive traces routed through the circuit substrate 202 may be reduced, which may enable improved signal integrity and routing flexibility.

In some implementations, a ratio between parallel signal connections and serial signal connections may be 37:4 or higher, depending on the communication protocol. In some implementations, a ratio between parallel signal connections and serial signal connections may be 74:4 or higher, depending on the communication protocol. Thus, the number of conductive traces routed through the circuit substrate 202 can be reduced significantly (e.g., from 37 to 4 or from 74 to 4, respectively).

As indicated above, FIG. 2A is provided as an example. Other examples may differ from what is described with regard to FIG. 2A.

FIG. 2B shows a semiconductor device assembly 200B according to one or more implementations. The semiconductor device assembly 200B may include a circuit substrate 202, a controller 204, a memory IC 206, a first serial-parallel management IC 208, and a second serial-parallel management IC 230.

The second serial-parallel management IC 230 may be configured to convert serial signals received on the one or more high-speed serial channels 210 into parallel signals. The serial-to-parallel conversion enables the second serial-parallel management IC 230 to provide the controller 204 with the same parallel bandwidth that was originally present at the memory IC 206. In the example shown in FIG. 2B, the first serial communication interface 214 may be part of the second serial-parallel management IC 230. Additionally, the second serial-parallel management IC 230 may include a third parallel communication interface 232, the controller 204 may include a fourth parallel communication interface 234, and conductive interface structures 236 may electrically couple the third parallel communication interface 232 and the fourth parallel communication interface 234 for parallel signaling between the controller 204 and the second serial-parallel management IC 230.

A host communication interface 238 may be provided for communicating with a host device (e.g., the host system 105). The host communication interface 238 may be a serial communication interface or a parallel communication interface. In some implementations, the host communication interface 238 is a two-wire communication interface, such as PCIe.

The controller 204 may have a corresponding host communication interface coupled to the host communication interface 238. In some implementations, the second serial-parallel management IC 230 may pass communications between the controller 204 and the host communication interface 238 (e.g., between the controller 204 and the host device). The second serial-parallel management IC 230 may be coupled to the host communication interface 238 by conductive interface structures 240. In some implementations, the controller 204 may be mounted to the circuit substrate 202 and coupled directly to the host communication interface 238 by the conductive interface structures 240.

As indicated above, FIG. 2B is provided as an example. Other examples may differ from what is described with regard to FIG. 2B.

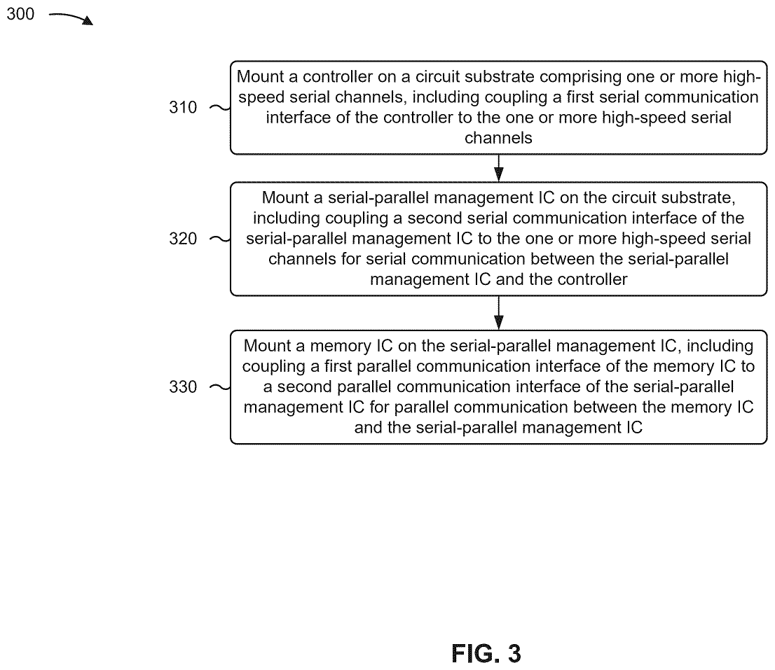

FIG. 3 is a flowchart of an example method 300 associated with reduced density routing of DRAM signals on circuit substrates, such as small form factor PCBs. In particular, the method 300 may correspond to a method for manufacturing a semiconductor device assembly. The semiconductor device assembly may be similar to the semiconductor device assembly 200A described in connection with FIG. 2A, or the semiconductor device assembly 200B described in connection with FIG. 2B.

As shown in FIG. 3, the method 300 may include mounting a controller on a circuit substrate comprising one or more high-speed serial channels, including coupling a first serial communication interface of the controller to the one or more high-speed serial channels (block 310). As further shown in FIG. 3, the method 300 may include mounting a serial-parallel management IC on the circuit substrate, including coupling a second serial communication interface of the serial-parallel management IC to the one or more high-speed serial channels for serial communication between the serial-parallel management IC and the controller (block 320). As further shown in FIG. 3, the method 300 may include mounting a memory IC on the serial-parallel management IC, including coupling a first parallel communication interface of the memory IC to a second parallel communication interface of the serial-parallel management IC for parallel communication between the memory IC and the serial-parallel management IC, wherein the serial-parallel management IC is configured as a serial-parallel communication interface between the controller and the memory IC (block 330).

The method 300 may include additional aspects, such as any single aspect or any combination of aspects described below and/or described in connection with one or more other methods or operations described elsewhere herein.

Although FIG. 3 shows example blocks of a method 300, in some implementations, the method 300 may include additional blocks, fewer blocks, different blocks, or differently arranged blocks than those depicted in FIG. 3. Additionally, or alternatively, two or more of the blocks of the method 300 may be performed in parallel. The method 300 is an example of one method that may be performed by one or more devices described herein. These one or more devices may perform or may be configured to perform one or more other methods based on operations described herein.

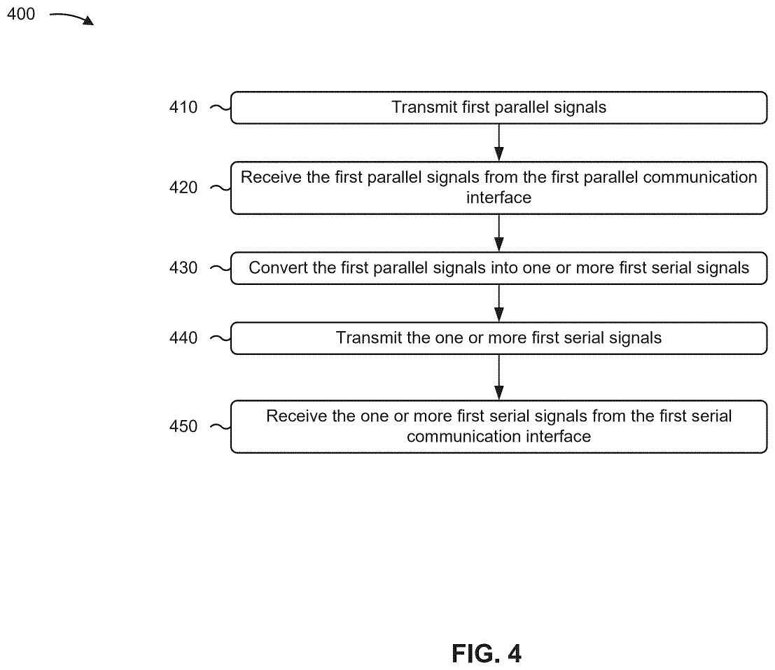

FIG. 4 is a flowchart of an example method 400 associated with reduced density routing of DRAM signals on circuit substrates, such as small form factor PCBs. In particular, the method 400 may correspond to a method of communicating between a controller and a memory IC. In some implementations, a semiconductor device assembly (e.g., the semiconductor device assembly 200A or 200B) may perform or may be configured to perform the method 400. In some implementations, another device or a group of devices separate from or including the semiconductor device assembly (e.g., host system 105) may perform or may be configured to perform part of the method 400. Additionally, or alternatively, one or more components of the semiconductor device assembly (e.g., controller 204, memory IC 206, and/or serial-parallel management IC 208) may perform or may be configured to perform the method 400. Thus, means for performing the method 400 may include the semiconductor device assembly and/or one or more components of the semiconductor device assembly. Additionally, or alternatively, a non-transitory computer-readable medium may store one or more instructions that, when executed by the semiconductor device assembly, cause the semiconductor device assembly to perform the method 400.

As shown in FIG. 4, the method 400 may include transmitting, by a first parallel communication interface of the memory IC, first parallel signals (block 410). As further shown in FIG. 4, the method 400 may include receiving, by a second parallel communication interface of a serial-parallel management IC, the first parallel signals from the first parallel communication interface (block 420). As further shown in FIG. 4, the method 400 may include converting, by the serial-parallel management IC, the first parallel signals into one or more first serial signals (block 430). As further shown in FIG. 4, the method 400 may include transmitting, by a first serial communication interface of the serial-parallel management IC, the one or more first serial signals (block 440). As further shown in FIG. 4, the method 400 may include receiving, by a second serial communication interface of the controller, the one or more first serial signals from the first serial communication interface (block 450). The first serial communication interface and the second serial communication interface are coupled by one or more serial channels.

The method 400 may include additional aspects, such as any single aspect or any combination of aspects described below and/or described in connection with one or more other methods or operations described elsewhere herein.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a semiconductor device assembly includes a circuit substrate comprising one or more high-speed serial channels; a controller arranged on the circuit substrate, wherein the controller comprises a first serial communication interface coupled to the one or more high-speed serial channels; a memory chip comprising a first parallel communication interface configured to transmit first parallel signals; and a serial management SOC arranged on the circuit substrate, wherein the serial management SOC comprises a second serial communication interface coupled to the one or more high-speed serial channels for communication with the controller, and a second parallel communication interface coupled to the first parallel communication interface of the memory chip, wherein the serial management SOC is configured to receive the first parallel signals from the memory chip via the second parallel communication interface, convert the first parallel signals into one or more first serial signals, and transmit the one or more first serial signals to the controller via the second serial communication interface and the one or more high-speed serial channels.

In some implementations, a semiconductor device assembly includes a circuit substrate comprising one or more high-speed serial channels; a controller arranged on the circuit substrate, wherein the controller comprises a first serial communication interface coupled to the one or more high-speed serial channels; a memory IC comprising a first parallel communication interface configured to transmit first parallel signals; and a serial-parallel management IC arranged on the circuit substrate, wherein the serial-parallel management IC comprises a second serial communication interface coupled to the one or more high-speed serial channels for communication with the controller, and a second parallel communication interface coupled to the first parallel communication interface of the memory IC, wherein the serial-parallel management IC is configured to receive the first parallel signals from the memory IC via the second parallel communication interface, convert the first parallel signals into one or more first serial signals, and transmit the one or more first serial signals to the controller via the second serial communication interface and the one or more high-speed serial channels.

In some implementations, a semiconductor device assembly includes a circuit substrate comprising one or more serial channels; a CXL controller arranged on the circuit substrate, wherein the CXL controller comprises a first serial communication interface coupled to the one or more serial channels; a DRAM IC comprising a first parallel communication interface configured to transmit first parallel signals; and a serial-parallel converter IC arranged on the circuit substrate, wherein the serial-parallel converter IC comprises a second serial communication interface coupled to the one or more serial channels for communication with the CXL controller, and a second parallel communication interface coupled to the first parallel communication interface of the DRAM IC, wherein the serial-parallel converter IC is configured to receive the first parallel signals from the DRAM IC via the second parallel communication interface, convert the first parallel signals into one or more first serial signals, and transmit the one or more first serial signals to the CXL controller via the second serial communication interface and the one or more serial channels.

In some implementations, a method of manufacturing a semiconductor device assembly includes mounting a controller on a circuit substrate comprising one or more high-speed serial channels, including coupling a first serial communication interface of the controller to the one or more high-speed serial channels; mounting a serial-parallel management IC on the circuit substrate, including coupling a second serial communication interface of the serial-parallel management IC to the one or more high-speed serial channels for serial communication between the serial-parallel management IC and the controller; and mounting a memory IC on the serial-parallel management IC, including coupling a first parallel communication interface of the memory IC to a second parallel communication interface of the serial-parallel management IC for parallel communication between the memory IC and the serial-parallel management IC, wherein the serial-parallel management IC is configured as a serial-parallel communication interface between the controller and the memory IC.

In some implementations, a method of communicating between a controller and a memory IC includes transmitting, by a first parallel communication interface of the memory IC, first parallel signals; receiving, by a second parallel communication interface of a serial-parallel management IC, the first parallel signals from the first parallel communication interface; converting, by the serial-parallel management IC, the first parallel signals into one or more first serial signals; transmitting, by a first serial communication interface of the serial-parallel management IC, the one or more first serial signals; and receiving, by a second serial communication interface of the controller, the one or more first serial signals from the first serial communication interface, wherein the first serial communication interface and the second serial communication interface are coupled by one or more serial channels.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more. ” Further, as used herein, the article “the” is intended to include one or more items referenced in connection with the article “the” and may be used interchangeably with “the one or more. ” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising one or more high-speed serial channels;
a controller arranged on the circuit substrate, wherein the controller comprises a first serial communication interface coupled to the one or more high-speed serial channels;
a memory chip comprising a first parallel communication interface configured to transmit first parallel signals; and
a serial management system-on-chip (SOC) arranged on the circuit substrate, wherein the serial management SOC comprises a second serial communication interface coupled to the one or more high-speed serial channels for communication with the controller, and a second parallel communication interface coupled to the first parallel communication interface of the memory chip,
wherein the serial management SOC is configured to receive the first parallel signals from the memory chip via the second parallel communication interface, convert the first parallel signals into one or more first serial signals, and transmit the one or more first serial signals to the controller via the second serial communication interface and the one or more high-speed serial channels.

2. The semiconductor device assembly of claim 1, wherein the first serial communication interface includes a first set of data queue (DQ) terminals coupled to the one or more high-speed serial channels and configured to receive the one or more first serial signals,
wherein the second serial communication interface includes a second set of DQ terminals coupled to the one or more high-speed serial channels and configured to transmit the one or more first serial signals, and
wherein the first parallel communication interface includes at least eight parallel DQ terminals coupled to respective DQ terminals of the second parallel communication interface for transferring the first parallel signals to the serial management SOC.

3. The semiconductor device assembly of claim 1, wherein the serial management SOC is configured to receive one or more second serial signals at the second serial communication interface from the controller, via the one or more high-speed serial channels, convert the one or more second serial signals into second parallel signals, and provide the second parallel signals to the memory chip via the second parallel communication interface.

4. The semiconductor device assembly of claim 3, wherein the first serial communication interface includes a first set of data queue (DQ) terminals coupled to the one or more high-speed serial channels and configured to transmit the one or more second serial signals,
wherein the second serial communication interface includes a second set of DQ terminals coupled to the one or more high-speed serial channels and configured to receive the one or more second serial signals, and
wherein the first parallel communication interface includes at least eight parallel DQ terminals coupled to the second parallel communication interface for transferring the second parallel signals from the serial management SOC to the memory chip.

5. The semiconductor device assembly of claim 1, wherein each high-speed serial channel of the one or more high-speed serial channels includes a two wires, forming a differential signal pair, configured to transmit signals via differential signaling.

6. The semiconductor device assembly of claim 1, wherein the first parallel communication interface includes a first number of data queue (DQ) terminals for transmitting the first parallel signals,
wherein the second serial communication interface includes a second number of DQ ports for transmitting the one or more first serial signals, and
wherein the first number is a first multiple of the second number, the first multiple being equal to the second number multiplied by a conversion factor.

7. The semiconductor device assembly of claim 6, wherein the first parallel communication interface is configured to transfer the first parallel signals at a first transmission rate,
wherein the second serial communication interface is configured to transfer the one or more first serial signals at a second transmission rate, and
wherein the second transmission rate is equal to or greater than a second multiple of the first transmission rate, the second multiple being equal to the first transmission rate multiplied by the conversion factor.

8. The semiconductor device assembly of claim 1, wherein each high-speed serial channel of the one or more high-speed serial channels is a differential signaling channel comprising a pair of traces.

9. The semiconductor device assembly of claim 1, wherein the memory chip is a dynamic random access memory (DRAM) chip.

10. The semiconductor device assembly of claim 1, wherein the memory chip is arranged on the serial management SOC such that the memory chip and the serial management SOC form a chip stack.

11. The semiconductor device assembly of claim 1, wherein the controller is a compute express link (CXL) controller.

12. The semiconductor device assembly of claim 1, wherein circuit substrate is a printed circuit board (PCB).

13. The semiconductor device assembly of claim 1, further comprising a package casing disposed over the circuit substrate, wherein the package casing encapsulates the controller, the memory chip, and the serial management SOC.

14. The semiconductor device assembly of claim 1, wherein the one or more high-speed serial channels include one or more control channels, or one or more data channels.

15. The semiconductor device assembly of claim 1, wherein the first parallel signals are parallel data signals, and
wherein the one or more first serial signals are serial data signals.

16. A semiconductor device assembly, comprising:
a circuit substrate comprising one or more high-speed serial channels;
a controller arranged on the circuit substrate, wherein the controller comprises a first serial communication interface coupled to the one or more high-speed serial channels;
a memory integrated circuit (IC) comprising a first parallel communication interface configured to transmit first parallel signals; and
a serial-parallel management IC arranged on the circuit substrate, wherein the serial-parallel management IC comprises a second serial communication interface coupled to the one or more high-speed serial channels for communication with the controller, and a second parallel communication interface coupled to the first parallel communication interface of the memory IC,
wherein the serial-parallel management IC is configured to receive the first parallel signals from the memory IC via the second parallel communication interface, convert the first parallel signals into one or more first serial signals, and transmit the one or more first serial signals to the controller via the second serial communication interface and the one or more high-speed serial channels.

17. The semiconductor device assembly of claim 16, wherein the memory IC is arranged on the serial-parallel management IC such that the memory IC and the serial-parallel management IC form a three-dimensional (3D) IC.

18. The semiconductor device assembly of claim 16, further comprising:
a first wafer comprising the memory IC; and
a second wafer comprising the serial-parallel management IC,
wherein the first wafer is arranged on the second wafer to from a three-dimensional (3D) wafer stack.

19. The semiconductor device assembly of claim 16, wherein the first parallel communication interface and the second parallel communication interface are vertically connected.

20. The semiconductor device assembly of claim 16, wherein the memory IC is a dynamic random access memory (DRAM) IC.

21. The semiconductor device assembly of claim 16, wherein each high-speed serial channel of the one or more high-speed serial channels is a differential signaling channel comprising a pair of electrically conductive paths.

22. The semiconductor device assembly of claim 16, wherein the serial-parallel management IC is configured to receive one or more second serial signals at the second serial communication interface from the controller, via the one or more high-speed serial channels, convert the one or more second serial signals into second parallel signals, and provide the second parallel signals to the memory IC via the second parallel communication interface.

23. The semiconductor device assembly of claim 16, wherein the first parallel communication interface includes a first number of data queue (DQ) terminals for transmitting the first parallel signals,
wherein the second serial communication interface includes a second number of DQ ports for transmitting the one or more first serial signals, and
wherein the first number is a first multiple of the second number, the first multiple being equal to the second number multiplied by a conversion factor.

24. The semiconductor device assembly of claim 23, wherein the first parallel communication interface is configured to transfer the first parallel signals at a first transmission rate,
wherein the second serial communication interface is configured to transfer the one or more first serial signals at a second transmission rate, and
wherein the second transmission rate is equal to or greater than a second multiple of the first transmission rate, the second multiple being equal to the first transmission rate multiplied by the conversion factor.

25. The semiconductor device assembly of claim 16, further comprising a package casing disposed over the circuit substrate, wherein the package casing encapsulates the controller, the memory IC, and the serial-parallel management IC.

26. The semiconductor device assembly of claim 16, wherein the one or more high-speed serial channels include one or more control channels, or one or more data channels.

27. The semiconductor device assembly of claim 16, wherein the first parallel signals are parallel data signals, and
wherein the one or more first serial signals are serial data signals.

28. A semiconductor device assembly, comprising:
a circuit substrate comprising one or more serial channels;
a compute express link (CXL) controller arranged on the circuit substrate, wherein the CXL controller comprises a first serial communication interface coupled to the one or more serial channels;
a dynamic random access memory (DRAM) integrated circuit (IC) comprising a first parallel communication interface configured to transmit first parallel signals; and
a serial-parallel converter IC arranged on the circuit substrate, wherein the serial-parallel converter IC comprises a second serial communication interface coupled to the one or more serial channels for communication with the CXL controller, and a second parallel communication interface coupled to the first parallel communication interface of the DRAM IC,
wherein the serial-parallel converter IC is configured to receive the first parallel signals from the DRAM IC via the second parallel communication interface, convert the first parallel signals into one or more first serial signals, and transmit the one or more first serial signals to the CXL controller via the second serial communication interface and the one or more serial channels.

29. The semiconductor device assembly of claim 28, wherein the DRAM IC is a first chip, the serial-parallel converter IC is a second chip, and the first chip is arranged on the second chip, forming a chip stack.

30. The semiconductor device assembly of claim 28, further comprising:
a first wafer comprising the DRAM IC; and
a second wafer comprising the serial-parallel converter IC,
wherein the first wafer is arranged on the second wafer to from a three-dimensional (3D) wafer stack.

31. The semiconductor device assembly of claim 28, wherein each serial channel of the one or more serial channels is a differential signaling channel comprising a pair of electrically conductive paths.

32. The semiconductor device assembly of claim 28, wherein the serial-parallel converter IC is configured to receive, via the one or more serial channels, one or more second serial signals from the CXL controller, convert the one or more second serial signals into second parallel signals, and provide the second parallel signals to the DRAM IC via the second parallel communication interface.

33. The semiconductor device assembly of claim 28, wherein the first parallel communication interface includes a first number of data queue (DQ) terminals for transmitting the first parallel signals,
wherein the second serial communication interface includes a second number of DQ ports for transmitting the one or more first serial signals, and
wherein the first number is a first multiple of the second number, the first multiple being equal to the second number multiplied by a conversion factor,
wherein the first parallel communication interface is configured to transfer the first parallel signals at a first transmission rate,
wherein the second serial communication interface is configured to transfer the one or more first serial signals at a second transmission rate, and
wherein the second transmission rate is equal to or greater than a second multiple of the first transmission rate, the second multiple being equal to the first transmission rate multiplied by the conversion factor.

34. A method of manufacturing a semiconductor device assembly, the method comprising:
mounting a controller on a circuit substrate comprising one or more high-speed serial channels, including coupling a first serial communication interface of the controller to the one or more high-speed serial channels;
mounting a serial-parallel management integrated circuit (IC) on the circuit substrate, including coupling a second serial communication interface of the serial-parallel management IC to the one or more high-speed serial channels for serial communication between the serial-parallel management IC and the controller; and
mounting a memory IC on the serial-parallel management IC, including coupling a first parallel communication interface of the memory IC to a second parallel communication interface of the serial-parallel management IC for parallel communication between the memory IC and the serial-parallel management IC,
wherein the serial-parallel management IC is configured as a serial-parallel communication interface between the controller and the memory IC.

35. A method of communicating between a controller and a memory integrated circuit (IC), the method comprising:
transmitting, by a first parallel communication interface of the memory IC, first parallel signals;
receiving, by a second parallel communication interface of a serial-parallel management IC, the first parallel signals from the first parallel communication interface;
converting, by the serial-parallel management IC, the first parallel signals into one or more first serial signals;
transmitting, by a first serial communication interface of the serial-parallel management IC, the one or more first serial signals; and
receiving, by a second serial communication interface of the controller, the one or more first serial signals from the first serial communication interface,
wherein the first serial communication interface and the second serial communication interface are coupled by one or more serial channels.
